(19) United States
(12) Patent Application Publication
(10) Pub. No.: US 2022/0320016 A1
(43) Pub. Date: Oct. 6, 2022

(54) INKJET PRINTING DEDICATED TEST PINS

(71) Applicant: QUALCOMM Incorporated, San Diego, CA (US)

(72) Inventors: Aniket PATIL, San Diego, CA (US); Hong Bok WE, San Diego, CA (US); Joan Rey Villarba BUOT, Escondido, CA (US)

(21) Appl. No.: 17/223,947

(22) Filed: Apr. 6, 2021

(51) Int. Cl. H01L 23/58; H01L 23/498; H01L 23/48; H01L 23/04; H05K 1/02

(52) U.S. Cl. CPC H01L 23/58; H01L 23/49816; H01L 23/481; H01L 23/04; H05K 1/0206

(57) ABSTRACT

In an aspect, an apparatus includes a package. The package includes a substrate, a plurality of components located on a top surface of the substrate, a plurality of ball pads located on a bottom surface of the substrate, a plurality of balls, and a plurality of test pads located on the bottom surface of the substrate. Individual balls of the plurality of balls are attached to individual ball pads of the plurality of ball pads.

### BACKGROUND OF THE DISCLOSURE

### 1. Field of the Disclosure

Aspects of this disclosure relate generally to semiconductor fabrication, and particularly to eliminating setting aside a portion of contacts (e.g., balls or pins) on an integrated circuit for test purposes by inkjet printing dedicated test pins for testing.

### 2. Description of the Related Art

In a semiconductor package, dedicated connections (vias and the like) are used for sensing (e.g., testing) a Power Distribution Network (PDN), power management IC (PMIC), or the like. In a single chip or a multiple chip module, multiple dies are placed along with multiple passives and other devices. The dies may be located on a substrate or inside the package.

To test a semiconductor, the semiconductor is mounted on a test printed circuit board PCB and sensing is done to check voltage levels, current levels, and the like at specific points. Sensing is performed at points, such as, for example, a hard macro (that specifies how the required logic elements are interconnected and specifies the physical pathways and wiring patterns between the components), a logic of the PMIC, a logic of the application processor die, and the like. The points where sensing is performed are exposed using a portion of the contacts (e.g., pins or balls), referred to as test pins. Typically, about 9% of the contacts of a semiconductor are dedicated to test pins.

After testing is complete, the test pins are not used again. For example, when the semiconductor is used in a manufactured product, the test pins are not used. Thus, a significant portion of the pins are wasted by dedicating a portion of the pins to be test pins as the test pins are used only during testing. For semiconductor packages with a restricted pin count, this is a waste of the available pins.

### SUMMARY

The following presents a simplified summary relating to one or more aspects disclosed herein. As such, the following summary should not be considered an extensive overview relating to all contemplated aspects, nor should the following summary be regarded to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In a first aspect, an apparatus includes a package. The package includes a substrate, a plurality of components located on a top surface of the substrate, a plurality of ball pads located on a bottom surface of the substrate, a plurality of balls, and a plurality of test pads located on the bottom surface of the substrate. Individual balls of the plurality of balls are attached to individual ball pads of the plurality of ball pads. In some aspects (e.g., prior to testing the package), individual test pins may be attached to individual test pads of the plurality of test pads. In other aspects, solder resist may be applied over individual test pads of the plurality of test pads to prevent access to the individual test pads.

In a second aspect, a method of fabricating a package may include attaching components to a top surface of a substrate, forming a plurality of ball pads on a bottom surface of the substrate, and attaching a plurality of balls to a plurality of ball pads. Individual balls of the plurality of balls are attached to individual ball pads of the plurality of ball pads. The method includes forming a plurality of test pads on the bottom surface of the substrate. In some aspects (e.g., prior to testing the package), individual test pins may be extruded on individual test pads of the plurality of test pads. In other aspects, solder resist may be applied over individual test pads of the plurality of test pads to prevent access to the individual test pads.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof. A more complete understanding of the present disclosure may be obtained by reference to the following Detailed Description when taken in conjunction with the accompanying Drawings. In the figures, the left-most digit(s) of a reference number identifies the figure in which the reference number first appears. The same reference numbers in different figures indicate similar or identical items.

FIG. 1 is a block diagram illustrating a semiconductor with inkjet printed test pins, according to various aspects of the disclosure.

FIG. 2 is a block diagram illustrating mounting a semiconductor with inkjet printed test pins on a test PCB, according to various aspects of the disclosure.

FIGS. 3A, 3B, 3C, and 3D illustrate a portion of a process to create a semiconductor that includes ball pads and test pads, according to aspects of the disclosure.

FIGS. 4A, 4B, and 4C illustrate a remaining portion of a process to create a semiconductor in which test pins are extruded before attaching balls, according to aspects of the disclosure.

FIGS. 5A, 5B, and 5C illustrate a remaining portion of a process to create a semiconductor in which test pins are extruded after balls are attached, according to aspects of the disclosure.

FIGS. 6A, 6B illustrate applying solder resist during semiconductor fabrication while leaving ball attaches open and covering pin attaches to enable balls to be attached, according to aspects of the disclosure.

FIG. 7 illustrates a process that includes attaching a plurality of test pins to a plurality of test pads, according to aspects of the disclosure.

FIG. 8 illustrates a process that includes printing test pins using inkjet printing, according to aspects of the disclosure.

FIG. 9 illustrates an exemplary mobile device in accordance with one or more aspects of the disclosure.

FIG. 10 illustrates various electronic devices that may be integrated with an integrated device or a semiconductor device in accordance with one or more aspects of the disclosure.

### DETAILED DESCRIPTION

Disclosed are systems and techniques to use a conductive paste to inkjet print multiple test pins in between the normal contacts (e.g., pins or balls) of a package. As used herein, the term “package” can refer to a device that includes one or more dies coupled to a substrate. In some aspects, the package may be configured as one or more functional modules or a System-on-a-chip (SoC) device. The test pins have a height that is less than the normal contacts. The balls (or pins) may have a height of between about 135 um (micrometers) to about 155 um while the test pins may have a height of between about 30 um to about 50 um. The test pins may be circular, oval, square, or rectangular shaped and may each have a length of between about 50 um to 100 um and a width of between about 50 um to 100 um. For ease of understanding, the test pins are illustrated as having a rectangular shape to distinguish the test pins from the balls (that have a circular or oval shape). The test pins may be either rectangular (including square) or oval (including circular) to enable the test pins to be extruded into an available space. The systems and techniques can be used for semiconductors using a ball grid array (BGA) pitch of 350 microns or greater. An advantage of this approach is that all pins of the package can be used to provide functionality rather than dedicating up to 9% of the pins for test purposes. The additional pins can be used to provide new functions that manufacturers can use when using the semiconductor in manufactured products. In addition, a form factor of the package may be reduced by removing pins that are dedicated to testing.

The test pins are extruded on the substrate in between the normal pattern used for contacts. The test pins replace the dedicated test sense pins in a conventional semiconductor. The test pins are inkjet printed to the substrate using a conductive paste. The test pins are soldered onto a printed circuit board (PCB) used to test the semiconductor by simultaneously using (1) a land grid array (LGA) attach to attach the test pins to the test PCB and (2) a BGA attach mechanism for the contacts (e.g., pins or balls) of the package. Thus, the test pins are generated for semiconductor packages that are mounted on a test board for testing. When the semiconductor package is manufactured for use in products, the test pins are not inkjet printed on the substrate. Test pads, on which the test pins are extruded and which are used to connect to internal sense lines are covered up (e.g., with a solder mask or similar) during manufacturing. Internally, the test pads hang or float on a last metal layer. Thus, the extruded test pins are absent from semiconductor packages designed for inclusion in a product. Thus, all of the normal contacts (e.g., pins or balls) are available for functional use because none of the normal contacts are reserved for test purposes.

When mounting a semiconductor package with extruded test pins on a test PCB, the test PCB has separate test attachment pads to connect to the extruded test pins. The semiconductor package with extruded test pins is mounted on the test PCB using a reflow or a surface mount (SMT) attach using 2 simultaneous processes: (a) a BGA attach mechanism for the normal pins or balls and (b) an LGA attach for the extruded test pins. A single reflow process is thus be used to attach both the normal package pins or balls and the extruded test pins. The semiconductor package contacts (e.g., pins or balls) may be added before or after the test pins are extruded onto the substrate.

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “example” and/or “example” are used herein to mean “serving as an example, instance, or illustration.” Any aspect described herein as “example” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

As a first example, an apparatus (e.g., that includes a package, such as a system-on-a-chip) includes a substrate, a plurality of components located on a top surface of the substrate, a plurality of ball pads located on a bottom surface of the substrate, a plurality of balls, a plurality of test pads located on the bottom surface of the substrate, and a plurality of test pins. Individual balls of the plurality of balls are attached to individual ball pads of the plurality of ball pads and individual test pins are attached to individual test pads of the plurality of test pads. The individual test pins are lower in height than the individual balls. Individual test pads of the plurality of test pads are located between adjacent balls of the plurality of balls. Individual test pads are located approximately equidistant from adjacent balls. Individual test pins of the plurality of test pins are connected to one or more sense lines. The plurality of test pins are attached to a printed circuit board using a land grid array (LGA) and the plurality of balls are attached to the printed circuit board using a ball grid array (BGA). The individual test pins of the plurality of test pins are configured to be accessed to test one or more parameters of one or more of: a Power Distribution Network (PDN), a power management IC (PMIC), or an application processor die. The package is included in an apparatus selected from the group consisting of: a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a base station, an access point, a radio frequency (RF) module, and a device in an automotive vehicle.

As a second example, a method of fabricating a package includes: attaching components to a top surface of a substrate, forming a plurality of ball pads on a bottom surface of the substrate, attaching a plurality of balls to a plurality of ball pads, forming a plurality of test pads located on the bottom surface of the substrate, and attaching a plurality of test pins to the plurality of test pads. Individual balls of the plurality of balls are attached to individual ball pads of the plurality of ball pads and individual test pins are attached to individual test pads of the plurality of test pads. The individual test pins are lower in height than the individual balls. The method may include performing either an organic solderability preservatives (OSP) finish or performing an electrolytic Nickle-Gold (Ni—Au) finish (e.g., in which a layer of Gold is plated over a base of electroplated nickel). The method may include applying a solder resist to a pin-attach layer without covering the plurality of ball pads and the plurality of test pads. The method may include substantially simultaneously extruding and curing a plurality of test pins to the pin-attach layer. For example, individual test pins may be extruded and cured on top of individual test pads of the plurality of test pads. The method may include attaching a plurality of balls to the pin-attach layer. For example, individual balls of the plurality of balls may be attached to individual ball pads of the plurality of ball pads. In some cases, the test pins may be extruded and cured before attaching the plurality of balls while in other cases the test pins may be extruded and cured after attaching the plurality of balls. Substantially simultaneously extruding and curing a plurality of test pins to the pin-attach layer may include extruding a conductive paste using a nozzle of an inkjet printer to create the plurality of test pins and curing the plurality of test pins using a laser flash lamp as the plurality of test pins are being extruded. The package may be mounted on to a printed circuit board (PCB) using a reflow process in which the plurality of test pins are attached to the printed circuit board using a land grid array (LGA) attachment process while simultaneously attaching the plurality of balls are attached to the printed circuit board using a ball grid array (BGA) attachment process. The individual test pins of the plurality of test pins are connected to one or more sense lines in the package. For example, the package may be mounted on a printed circuit board (PCB) and the one or more sense lines accessed using the individual test pins. The one or more sense lines may be used to test one or more parameters of at least one of: a Power Distribution Network (PDN), a power management integrated circuit (PMIC), or an application processor die.

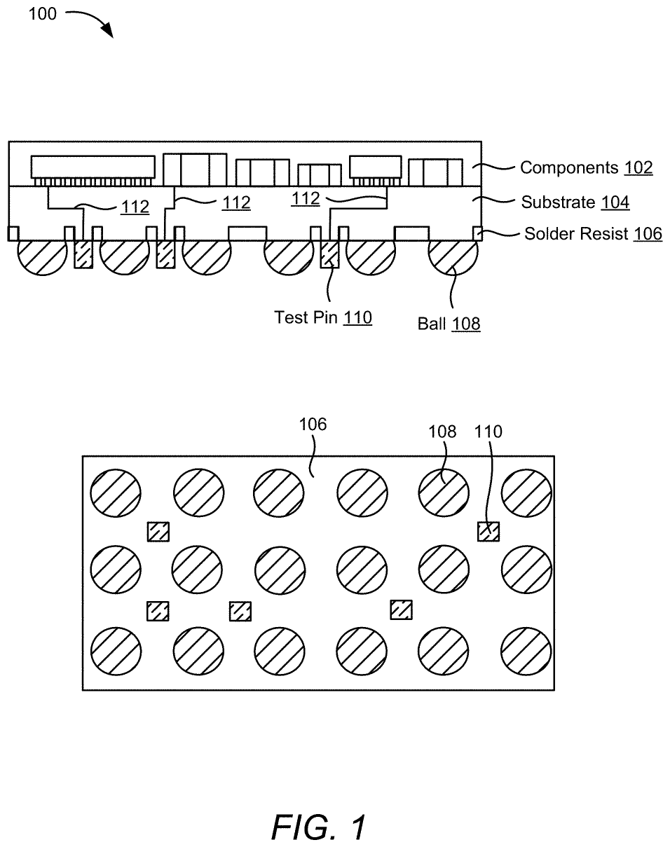

FIG. 1 is a block diagram illustrating a package 100 (e.g., a semiconductor) with inkjet printed test pins, according to various aspects of the disclosure. As used herein, the term “package” refers to a device that includes one or more dies coupled to a substrate. In some aspects, the package may be configured as one or more functional modules or a System-on-a-chip (SoC) device. The package 100 includes multiple components 102 located on top of a substrate 104. Solder resist 106 is located on portions of a bottom surface of the package 100. For example, in locations where the solder resist 106 is absent, the bottom of the package 100 includes multiple balls 108 and multiple test pins 110. Each test pin 110 is located approximately an equal distance from adjacent balls 108. The test pins 110 enable access to sense lines 112 internal to the package 100 to enable testing of a Power Distribution Network (PDN), a power management IC (PMIC), and the like. For ease of understanding, the test pins 110 are illustrated as having a rectangular shape to distinguish from the balls 108 (that have a circular or oval shape). However, it should be understood that the test pins 110 may have any type of geometric shape (e.g., rectangular, oval, or the like).

Each of the balls 108 may be used to provide functionality to the components of the package 100, with none of the balls 108 being reserved for use in sensing or testing. The balls 108 may be arranged in a conventional pattern associated with, for example, a ball grid array (BGA) or other type of package. Of course, while the balls 108 are illustrated in FIG. 1, another type of contact such as pins, may be used to mount the package 100 to a printed circuit board (PCB).

The test pins 110 are extruded onto the bottom of the package 100 using a conductive paste using an inkjet printer, either before the balls 108 are added or after the balls 108 are added to the package 100. A height of each test pin 110 is less than a height of each ball 108. The sense lines 112 connect from the die/package (e.g., active device) to test features (e.g., for PDN, PMIC, and the like). In some cases, the sense lines 112 may connect from passive devices (e.g., inductor/capacitor) to test features. The sense lines 112 are shown in a cross-sectional view of the package 100.

Thus, using an inkjet printer to extrude test pins between contacts (e.g., balls or pins) of a package prior to testing, the test pins enable access to internal sense lines to perform various measurements when testing the package. An advantage of using an inkjet printer to extrude test pins for testing is that all of the package's contacts can be used to provide functionality and avoids the conventional approach of dedicating a portion (e.g., up to 9%) of the contacts to access internal sense lines. In the conventional approach, reserving a portion of the contacts to access the internal sense lines results in “reserved” contacts that are not used when the package is incorporated in a product. The extruded test pins can be used with, for example, an access point (AP) module, a radio frequency (RF) module, or any process module which includes a PMIC system. The extruded test pins can be used for a single die package which has PDN test sense lines.

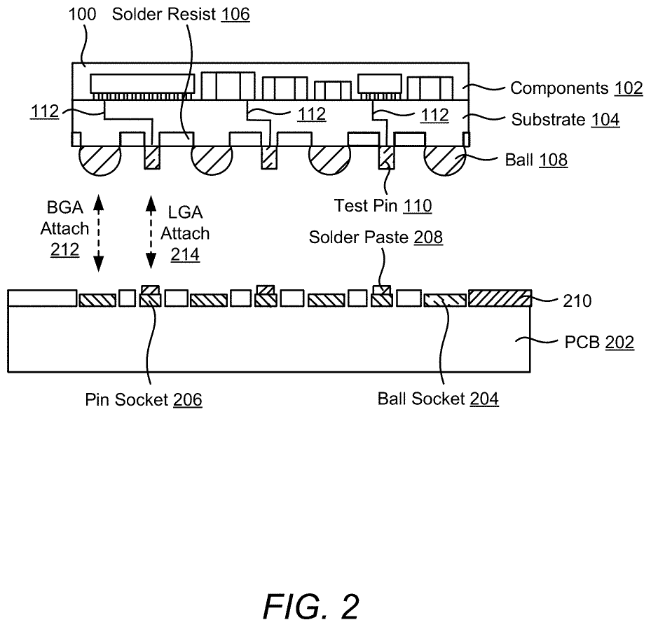

FIG. 2 is a block diagram 200 illustrating mounting a semiconductor with inkjet printed test pins on a test PCB, according to various aspects of the disclosure. To test the package 100, the package 100 may be mounted onto a printed circuit board (PCB) that is specifically designed to test the package 100. The mounting process proceeds as follows.

The balls 108 of the package 100 are lined up with ball sockets 204 on the PCB 202. Solder paste 208 is printed above each pin socket 206 in openings of solder resist 210 in the PCB 202. Each test pin 110 of the package 100 is soldered to the pin socket 206 using the solder paste 208.

The package 100 is mounted on the test PCB 202 in a single reflow using two simultaneous processes: (a) a ball grid array (BGA) attachment mechanism 212 to attach the balls 108 to the ball sockets 204 and (b) a land grid array (LGA) attachment mechanism 214 to attach the extruded test pins 110 to the pin sockets 206. The test pins 110 enable the PCB 202 to access the sense lines 112 to test various features of the package 100. When the package 100 is used in a manufactured product, the test pins 110 are absent, preventing access to the sense lines 112.

Thus, after the extruded test pins have been added to the package, the package is mounted to a test PCB in a straightforward reflow process simultaneously using BGA and LGA attachment mechanisms, e.g., to attaching the package with the test pins to the test PCB does not involve an exotic, unusual, complex, or expensive mechanism.

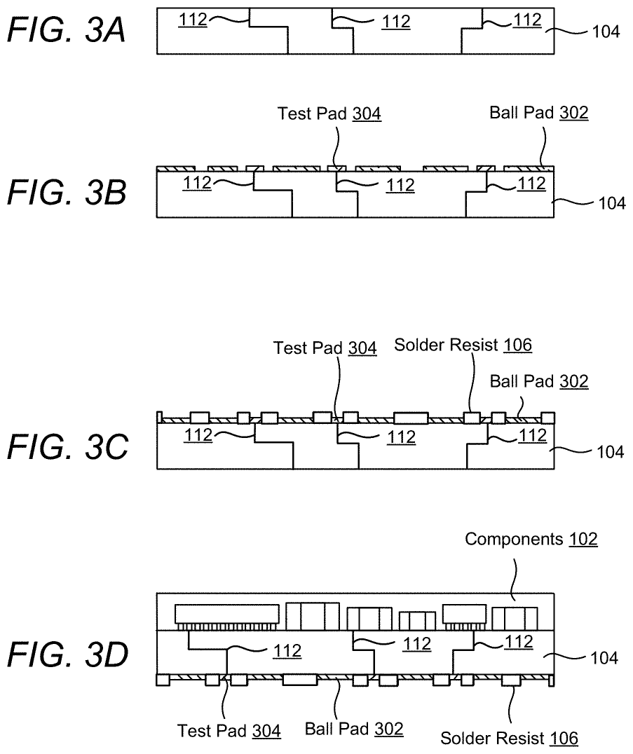

FIGS. 3A, 3B, 3C, and 3D illustrate a portion of a process to create a semiconductor that includes ball pads and test pads, according to aspects of the disclosure. The process may be performed when manufacturing a semiconductor package, such as the package 100 of FIGS. 1 and 2.

FIG. 3A illustrates building up the substrate 104. The substrate 104 may include multiple layers (e.g., 2 to 20 or more layers in some cases). Each layer of the substrate 104 is added through multiple processes, such as, for example, cored substrate, coreless substrate, Ajinomoto Build-up Film (ABF) process and the like. The build-up of the substrate 104 may include building each layer, such as, laminate, patterning on Cu (Copper), expose, develop, and so on. The build-up of the substrate 104 may include adding the sense lines 112 to the substrate 104.

FIG. 3B illustrates adding the ball pads 302 and the test pads 304. The test pads 304 enable access to the sense lines 112 in the substrate 104. FIG. 3C illustrates adding solder resist 106 (e.g., a solder mask) to portions of the upper surface of the substrate 104. In particular, the solder resist 106 does not cover the ball pads 302 and does not cover the test pads 304 to enable the balls and the test pins to be attached to the substrate 104 at a later point in the process. FIG. 3D illustrates adding the components 102 on an opposite side from the ball pads 302 and the test pads 304.

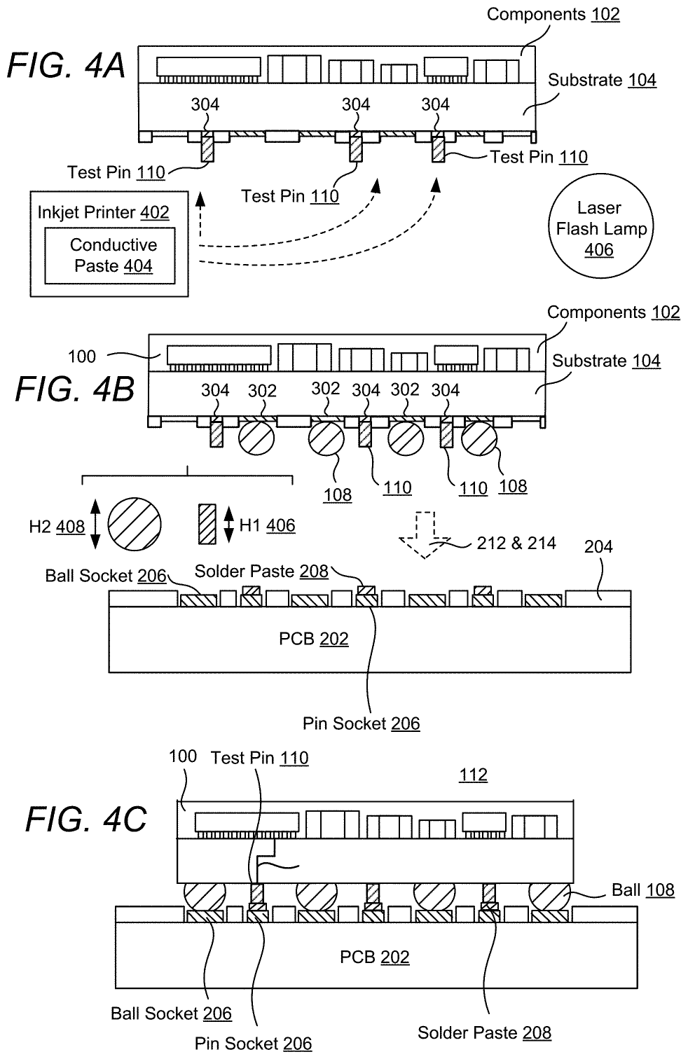

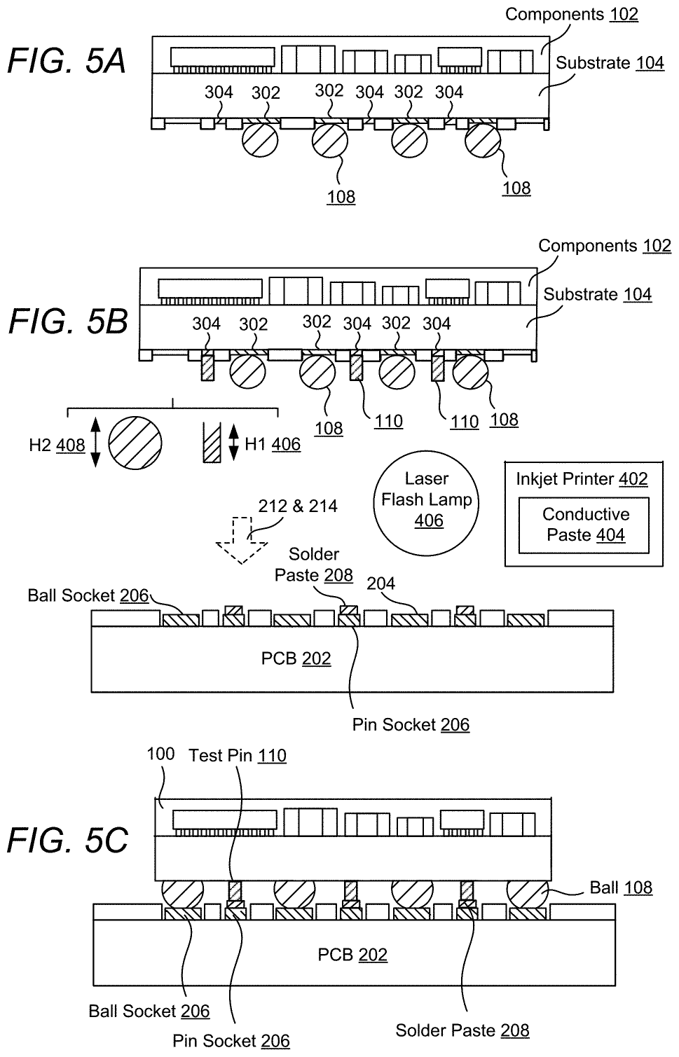

The portion of the process illustrated by FIGS. 3A, 3B, 3C, and 3D may be completed using either the process shown in FIGS. 4A, 4B, and 4C or the process shown in FIGS. 5A, 5B, and 5C. For ease of understanding, the sense lines 112 are not illustrated in the remaining figures but it should be understood that the sense lines 112 are present in FIGS. 4A, 4B, and 4C and FIGS. 5A, 5B, and 5C.

FIGS. 4A, 4B, and 4C illustrate a remaining portion of a process to create a semiconductor in which test pins are extruded before attaching balls, according to aspects of the disclosure.

FIG. 4A illustrates using an inkjet printer 402 with sintering to extrude conductive paste 404 to create the test pins 110 on top of the test pads 304. Sintering (also known as frittage) is a process that includes compacting and forming a solid mass, e.g., each of the test pins 110, using the extruded conductive paste 404. The test pins 110 are extruded preferably after a surface mount technology (SMT) process has been performed. A laser flash lamp 406 is used to cure the test pins 110, e.g., without using an oven to cure. The test pins 110 are printed and cured substantially simultaneously to enable each of the test pins 110 to maintain a vertical shape and geometry. The laser flash lamp 406 uses photonic curing, a process in which the extruded conductive paste 404 is exposed to pulsed light from the laser flash lamp 406 for about 1 millisecond (ms).

Each of the test pins 110 has a height H1 406 that is less than a height H2 408 of each of the balls 108. FIG. 4B illustrates printing the solder paste 208 on each pin socket 206 prior to mounting the package 100 to the PCB 202. FIG. 4C illustrates the package 100 mounted to the test PCB 202, with each of the balls 108 attached to a corresponding ball socket 204 (e.g., using the BGA attachment mechanism 212) and each of the test pins 110 attached to a corresponding pin socket 206 (e.g., using the LGA attachment mechanism 214).

FIGS. 5A, 5B, and 5C illustrate a remaining portion of a process to create a semiconductor in which test pins are extruded after balls are attached, according to aspects of the disclosure. FIG. 5A illustrates attaching each of the balls 108 to each of the ball pads 302.

FIG. 5B illustrates using the inkjet printer 402 with sintering to extrude the conductive paste 404 to create the test pins 110 on top of the test pads 304. The test pins 110 are extruded preferably after a surface mount technology (SMT) process has been performed. The laser flash lamp 406 is used to cure the test pins 110, e.g., without using an oven to cure. The test pins 110 are printed and cured substantially simultaneously to enable each of the test pins 110 to maintain a vertical shape and geometry. The height H1 406 of each test pin 110 is less than the height H2 408 of each of the balls 108. FIG. 5B illustrates placing the solder paste 208 on each pin socket 206 prior to mounting the package 100 to the PCB 202. FIG. 5C illustrates the package 100 mounted to the test PCB 202, with each of the balls 108 attached to a corresponding ball socket 204 (e.g., using the BGA attachment mechanism 212) and each of the test pins 110 attached to a corresponding pin socket 206 (e.g., using the LGA attachment mechanism 214).

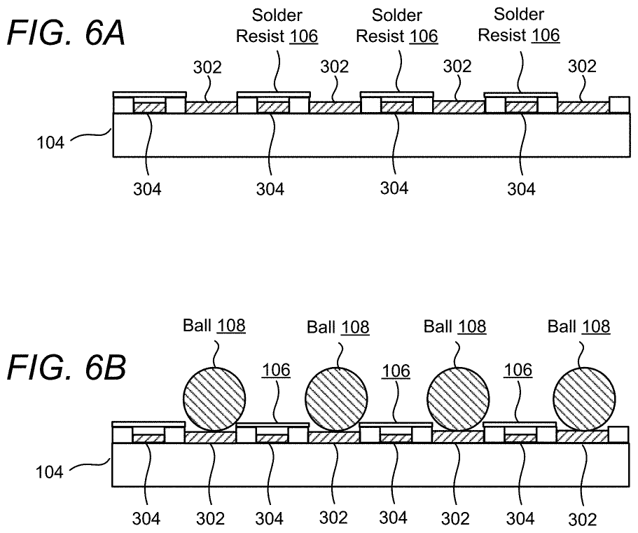

FIGS. 6A, 6B illustrate applying solder resist during semiconductor fabrication while leaving ball attaches open and covering pin attaches to enable balls to be attached, according to aspects of the disclosure. FIG. 6A illustrates applying the solder resist 106 during semiconductor fabrication such that the ball pads 302 are open (e.g., uncovered) and the test pads 304 are covered with the solder resist 106. This is done when manufacturing, for example a package that will be incorporated into a product (e.g., rather than being attached to a test PCB for test purposes). FIG. 6B illustrates attaching two of the balls 108 to two of the corresponding ball pads 302. The test pads 304 remain covered with the solder resist 106, making the sense lines (e.g., such as the representative sense line 306 of FIG. 3B) inaccessible.

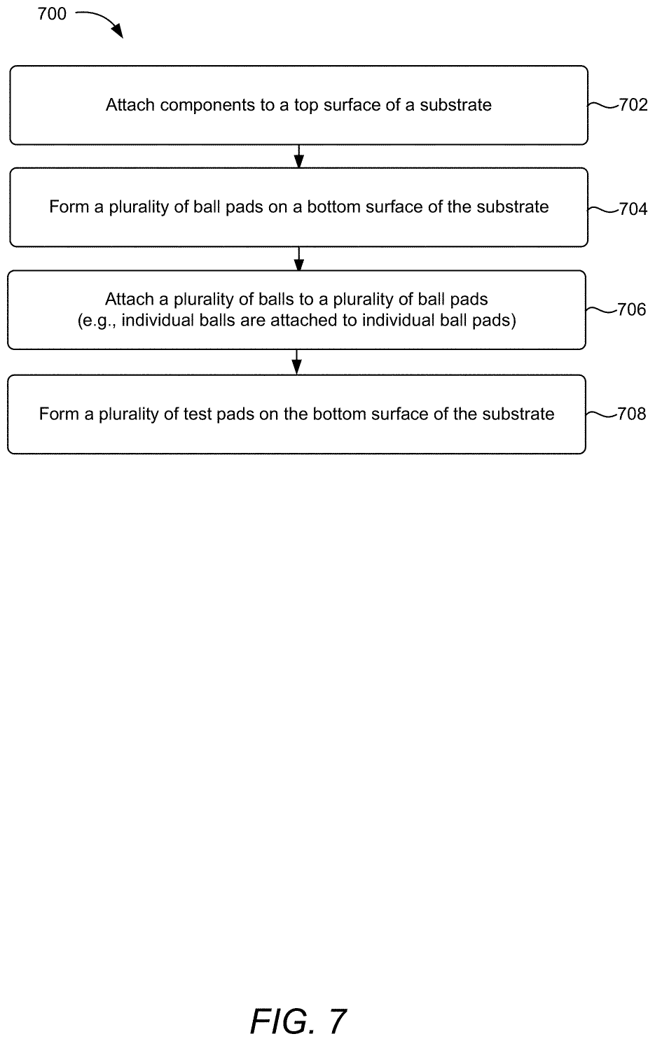

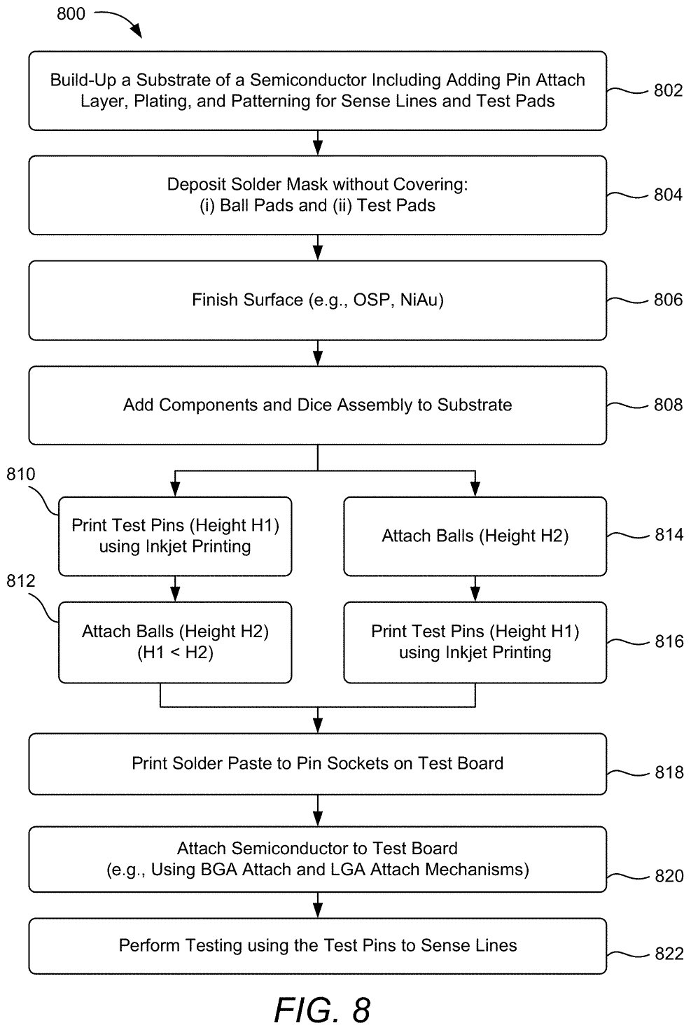

In the flow diagrams of FIGS. 7 and 8 each block represents one or more operations that can be implemented in hardware, software, or a combination thereof. In the context of software, the blocks represent computer-executable instructions that, when executed by one or more processors, cause the processors to perform the recited operations. Generally, computer-executable instructions include routines, programs, objects, modules, components, data structures, and the like that perform particular functions or implement particular abstract data types. The order in which the blocks are described is not intended to be construed as a limitation, and any number of the described operations can be combined in any order and/or in parallel to implement the processes. For discussion purposes, the processes 700 and 800 is described with reference to FIGS. 1, 2, 3A-3C, 4A-4C, 5A-5C, and 6A-6B as described above, although other models, frameworks, systems and environments may be used to implement these processes.

FIG. 7 illustrates a process 700 that includes attaching a plurality of test pins to a plurality of test pads, according to aspects of the disclosure. The process may be performed as part of a semiconductor manufacturing process, portions of which are described herein.

At 702, the process attaches components to a top surface of a substrate. For example, in FIG. 3D, the components 102 are attached to the substrate 104.

At 704, a plurality of ball pads are formed on a bottom surface of the substrate. At 706, the process attaches a plurality of balls to the plurality of ball pads (e.g., with individual balls being attached to individual ball pads). For example, in FIGS. 4B and 5A, the individual balls 108 are formed and attached to individual ones of the ball pads 302.

At 708, the process forms a plurality of test pads on the bottom surface of the substrate. For example, in FIG. 3B, the test pads 304 are formed on the substrate 104. If the package is to be used in a manufactured product, then the process may cover the test pads 304 with solder resist 106, as illustrated in FIG. 6A. If the package is to be used for testing, then the process may extrude the test pins 110 on the test pads 304, as illustrated in FIG. 4A and FIG. 5B.

Thus, a package is manufactured with test pads. Prior to testing the package, an inkjet printer is used to extrude test pins between contacts (e.g., balls or pins) of the package. The test pins enable access to internal sense lines to determine various parameters when testing the package. A technical advantage of using an inkjet printer to extrude test pins for testing is that all of the package's contacts can be used to provide functionality instead of dedicating a portion (e.g., up to 9%) of the contacts to access internal sense lines. By not reserving a portion of the contacts to access the internal sense lines, all contacts can be used when the package is incorporated in a product. In some cases, as a further technical advantage, not reserving a portion of the contacts may enable the number of contacts to be reduced, thereby reducing a form factor of the package. As consumer products, such as user equipment (UE) shrink in size, the form factor of packages used in the UE can be reduced, without reducing functionality. Alternately, as a further technical advantage, using all of the contacts in the package may enable additional functions to be provided. The extruded test pins can be used with, for example, an access point (AP) module, a radio frequency (RF) module, or any process module which includes a PMIC system. The extruded test pins can be used, for example, with a single die package which has PDN test sense lines. After testing has been completed and the package is ready for manufacturing, the test pads are covered with solder resist. A technical advantage of covering the test pads with solder resist when the package is manufactured for inclusion in a product (e.g., user equipment) is that the solder resist prevents access to the test pads and to the internal sense lines in the package.

FIG. 8 illustrates a process 800 that includes printing test pins using inkjet printing, according to aspects of the disclosure. The process may be performed as part of a semiconductor manufacturing process, portions of which are described herein.

At 802, the process builds up a substrate of a semiconductor including adding a pin-attach layer, plating and patterning for sense lines and test pads. For example, in FIG. 3B, a semiconductor is built using the substrate 104 and adding a pin-attach layer (e.g., a final metal layer), Copper (Cu) plating, and patterning. The process includes adding the test pads 304 and the ball pads 302.

At 804, the process deposits a solder mask without covering ball pads and test pads. At 806, the process finishes the surface. For example, in FIG. 3C, the solder resist 106 is added without covering the ball pads 302 and the test pads 304. The entire surface is finished using, for example, an organic solderability preservatives (OSP) finish, an electrolytic Ni—Au (Nickle-Gold) finish (e.g., a layer of Gold, plated over a base of electroplated nickel), or similar.

At 808, the process adds components and dice assembly to the substrate. For example, in FIG. 3D, the components 102 are added to the substrate 104.

In some aspects (e.g., extruding test pins before attaching balls), at 810, the process prints the test pins, at a height H1, using inkjet printing. At 812, the process attaches balls that have a height H2 (H1<H2). For example, in FIGS. 4A and 4B, the inkjet printer 402 is used to extrude the conductive paste 404 using sintering to create the test pins 110 over the test pads 304. The test pins 110 are cured using the laser flash lamp 406 substantially at the same time as they are being printed. After the test pins 110 have been printed and cured, each of the balls 108 are attached to the corresponding one of the ball pads 302.

In other aspects (e.g., extruding test pins after attaching balls), at 814, the process attaches balls that have a height H2. At 816, the process prints the test pins, having a height H1 (H1<H2), by using an inkjet printer (e.g., to extrude the test pins using conductive paste). For example, in FIGS. 5A and 5B, each of the balls 108 are attached to the corresponding one of the ball pads 302. After the balls 108 are attached, the inkjet printer 402 is used to extrude the conductive paste 404 using sintering to create the test pins 110 over the test pads 304. The test pins 110 are cured using the laser flash lamp 406 substantially at the same time as they are being printed.

At 818, the process prints solder paste to pin sockets on a test board. At 820, the semiconductor is attached to the test board. At 822, testing is performed using the test pins to access sense lines in the semiconductor. For example, in FIGS. 4B, 4C, 5B, 5C, the solder paste 208 is applied to each of the pin sockets 206 of the PCB 202. The package 100 is mounted to the test PCB 202, with each of the balls 108 attached to a corresponding ball socket 204 (e.g., using the BGA attachment mechanism 212) and each of the test pins 110 attached to a corresponding pin socket 206 (e.g., using the LGA attachment mechanism 214).

Thus, a package that includes test pads is manufactured. Prior to testing the package, an inkjet printer is used to extrude test pins between contacts (e.g., balls or pins) of the package. When testing the package, the test pins enable access to internal sense lines to determine various parameters. A technical advantage of using an inkjet printer to extrude test pins is that all of the package's contacts can be used to provide functionality thereby avoiding dedicating a portion (e.g., up to 9%) of the contacts to access internal sense lines. A size of the package may be decreased if fewer contacts are used or the manufacturer offer access to additional functions via contacts that were previously reserved for testing. After testing is complete and the package is ready to be manufactured for inclusion in a customer product (e.g., a user equipment), the test pads are covered using solder resist. A technical advantage of the solder resist is to prevent access to the test pads and to the internal sense lines.

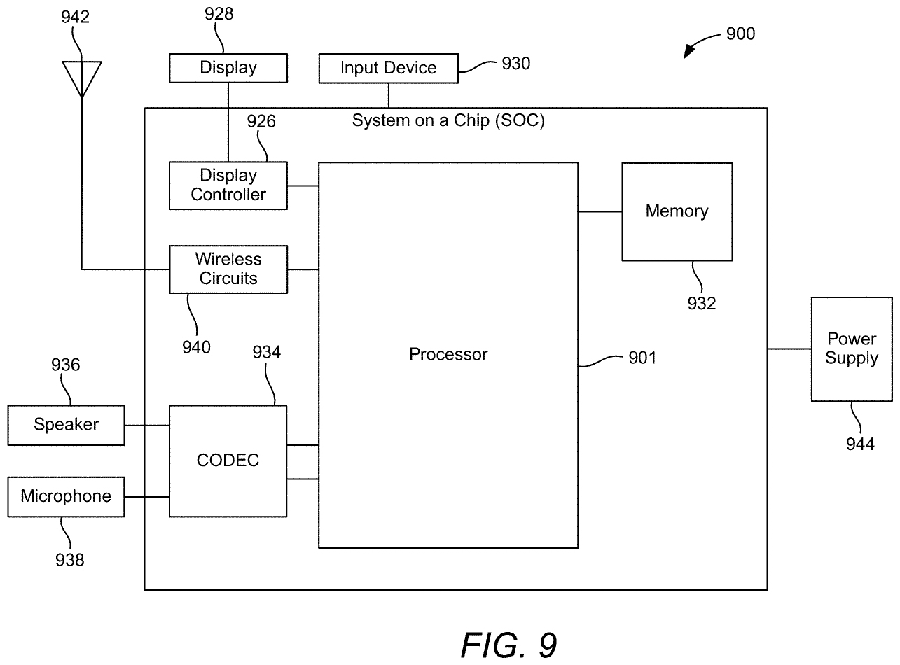

FIG. 9 illustrates an exemplary mobile device incorporating a system-on-chip (SOC) 900 in accordance with some examples of the disclosure. In some aspects, the mobile device of FIG. 9 may be configured as a wireless communication device. As shown, the mobile device of FIG. 9 includes processor 901. Processor 901 may be communicatively coupled to memory 932 over a link, which may be a die-to-die or chip-to-chip link. Processor 901 is a hardware device capable of executing logic instructions. The mobile device of FIG. 9 also includes display 928 and display controller 926, with display controller 926 coupled to processor 901 and to display 928.

In some aspects, FIG. 9 may include coder/decoder (CODEC) 934 (e.g., an audio and/or voice CODEC) coupled to processor 901; speaker 936 and microphone 938 coupled to CODEC 934; and wireless circuits 940 (which may include a modem, RF circuitry, filters, etc., which may be implemented using ball sockets 204 and pin sockets 206) coupled to wireless antenna 942 and to processor 901.

In a particular aspect, where one or more of the above-mentioned blocks are present, processor 901, display controller 926, memory 932, CODEC 934, and wireless circuits 940 can be included in the SOC 900 which may be implemented in whole or part using the pin sockets 206 and the ball sockets 204 disclosed herein. Input device 930 (e.g., physical or virtual keyboard), power supply 944 (e.g., battery), display 928, input device 930, speaker 936, microphone 938, wireless antenna 942, and power supply 944 may be external to SOC 900 and may be coupled to a component of SOC 900, such as an interface or a controller.

One or more of the components, such as the processor 901, the memory 932, the display controller 926, the wireless circuits 940, and the codec 934 may be manufactured using the systems and techniques described here, e.g., with inkjet printed test pins to access internal sense lines of the component when the component is mounted on a test PCB for testing. The test pins may not be printed when the component is manufactured for inclusion in a product, such as the mobile device of FIG. 9.

It should be noted that although FIG. 9 depicts a mobile device, processor 901 and memory 932 may also be integrated into a set top box, a music player, a video player, an entertainment unit, a navigation device, a personal digital assistant (PDA), a fixed location data unit, a computer, a laptop, a tablet, a communications device, a mobile phone, or other similar devices.

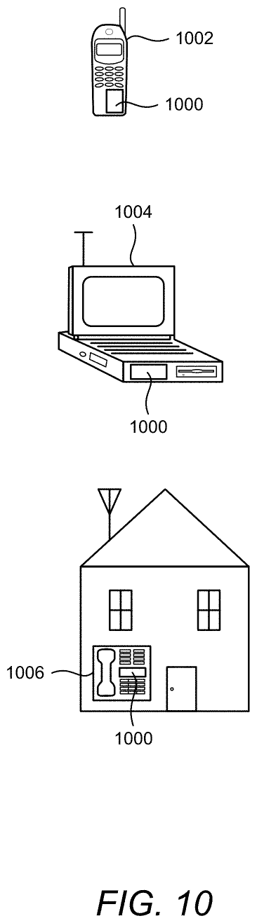

FIG. 10 illustrates various electronic devices that may be integrated with any of the aforementioned integrated device or semiconductor packages accordance with various examples of the disclosure. For example, a mobile phone device 1002, a laptop computer device 1004, and a fixed location terminal device 1006 may each be considered generally user equipment (UE) and may include a package 1000 as described herein. The package 1000 may be, for example, any of the integrated circuits, dies, integrated devices, integrated device packages, integrated circuit devices, device packages, integrated circuit (IC) packages, package-on-package devices described herein. The devices 1002, 1004, 1006 illustrated in FIG. 10 are merely exemplary. Other electronic devices may also feature the package 1000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

It can be noted that, although particular frequencies, integrated circuits (ICs), hardware, and other features are described in the aspects herein, alternative aspects may vary. That is, alternative aspects may utilize additional or alternative frequencies (e.g., other the 60 GHz and/or 28 GHz frequency bands), antenna elements (e.g., having different size/shape of antenna element arrays), scanning periods (including both static and dynamic scanning periods), electronic devices (e.g., WLAN APs, cellular base stations, smart speakers, IoT devices, mobile phones, tablets, personal computer (PC), etc.), and/or other features. A person of ordinary skill in the art will appreciate such variations.

It should be understood that any reference to an element herein using a designation such as “first,” “second,” and so forth does not generally limit the quantity or order of those elements. Rather, these designations may be used herein as a convenient method of distinguishing between two or more elements or instances of an element. Thus, a reference to first and second elements does not mean that only two elements may be employed there or that the first element must precede the second element in some manner. Also, unless stated otherwise a set of elements may comprise one or more elements. In addition, terminology of the form “at least one of A, B, or C” or “one or more of A, B, or C” or “at least one of the group consisting of A, B, and C” used in the description or the claims means “A or B or C or any combination of these elements.” For example, this terminology may include A, or B, or C, or A and B, or A and C, or A and B and C, or 2A, or 2B, or 2C, and so on.

In view of the descriptions and explanations above, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses claims should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an insulator and a conductor). Furthermore, it is also intended that aspects of a clause can be included in any other independent clause, even if the clause is not directly dependent on the independent clause. Implementation examples are described in the following numbered clauses:

Clause 1. A method of fabricating a package, the method comprising: attaching components to a top surface of a substrate; forming a plurality of ball pads on a bottom surface of the substrate; attaching a plurality of balls to a plurality of ball pads, wherein individual balls of the plurality of balls are attached to individual ball pads of the plurality of ball pads; and forming a plurality of test pads on the bottom surface of the substrate.

Clause 2. The method of clause 1, further comprising: attaching a plurality of test pins to the plurality of test pads, wherein individual test pins are attached to individual test pads of the plurality of test pads, and wherein the individual test pins are lower in height than the individual balls.

Clause 3. The method of clause 2, further comprising: applying a solder resist to a pin-attach layer, wherein the plurality of ball pads and the plurality of test pads are not covered by the solder resist; and substantially simultaneously extruding and curing the plurality of test pins to the pin-attach layer, wherein individual test pins are extruded and cured on top of individual test pads of the plurality of test pads.

Clause 4. The method of clause 3, wherein substantially simultaneously extruding and curing the plurality of test pins to the pin-attach layer comprises: extruding a conductive paste using a nozzle of an inkjet printer to create the plurality of test pins; and curing the plurality of test pins using a laser flash lamp as the plurality of test pins are being extruded.

Clause 5. The method of any of clauses 2 to 4, wherein the package is mounted on to a printed circuit board (PCB) using a reflow process comprising: attaching the plurality of test pins to the printed circuit board using a land grid array (LGA) attachment process; and attaching the plurality of balls to the printed circuit board using a ball grid array (BGA) attachment process.

Clause 6. The method of any of clauses 2 to 5, wherein the individual test pins of the plurality of test pins are connected to one or more sense lines located in the package.

Clause 7. The method of clause 6, further comprising: mounting the package on a printed circuit board (PCB); and accessing the one or more sense lines using one or more individual test pins.

Clause 8. The method of clause 7, further comprising: testing, using the one or more sense lines, one or more parameters of at least one of a Power Distribution Network (PDN), a power management integrated circuit (PMIC), or an application processor die.

Clause 9. The method of any of clauses 2 to 8, wherein each pin of the plurality of test pins has a height of between about 30 micrometers to about 50 micrometers.

Clause 10. The method of any of clauses 2 to 9, wherein the plurality of test pins has a generally circular, oval, square, or rectangular shape.

Clause 11. The method of any of clauses 2 to 10, wherein at least one test pin of the plurality of test pins is located between four adjacent balls of the plurality of balls.

Clause 12. The method of any of clauses 1 to 11, further comprising: performing an organic solderability preservatives (OSP) finish; or performing an electrolytic Nickle-Gold (Ni—Au) finish in which a layer of Gold is plated over a base of electroplated nickel.

Clause 13. The method of any of clauses 1 to 12, wherein each of the plurality of balls has a height of between about 135 micrometers to about 155 micrometers.

Clause 14. The method of any of clauses 1 to 13, wherein the package comprises a System-on-a-chip (SOC).

Clause 15. The method of any of clauses 1 to 14, wherein the package is incorporated into a device that is selected from the group consisting of: a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a base station, and an automotive-based device in an automotive vehicle.

Accordingly, it will be appreciated, for example, that an apparatus or any component of an apparatus may be configured to (or made operable to or adapted to) provide functionality as taught herein. This may be achieved, for example: by manufacturing (e.g., fabricating) the apparatus or component so that it will provide the functionality; by programming the apparatus or component so that it will provide the functionality; or through the use of some other suitable implementation technique. As one example, an integrated circuit may be fabricated to provide the requisite functionality. As another example, an integrated circuit may be fabricated to support the requisite functionality and then configured (e.g., via programming) to provide the requisite functionality. As yet another example, a processor circuit may execute code to provide the requisite functionality.

Moreover, the methods, sequences, and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor (e.g., cache memory).

While the foregoing disclosure shows various illustrative aspects, it should be noted that various changes and modifications may be made to the illustrated examples without departing from the scope defined by the appended claims. The present disclosure is not intended to be limited to the specifically illustrated examples alone. For example, unless otherwise noted, the functions, steps, and/or actions of the method claims in accordance with the aspects of the disclosure described herein need not be performed in any particular order. Furthermore, although certain aspects may be described or claimed in the singular, the plural is contemplated unless limitation to the singular is explicitly stated.

1. An apparatus including a package comprising:
a substrate;
a plurality of components located on a top surface of the substrate;
a plurality of ball pads located on a bottom surface of the substrate;
a plurality of balls, wherein individual balls of the plurality of balls are attached to individual ball pads of the plurality of ball pads; and
a plurality of test pads located on the bottom surface of the substrate.

2. The apparatus of claim 1, further comprising
a plurality of test pins, wherein individual test pins are attached to individual test pads of the plurality of test pads and the individual test pins are lower in height than the individual balls.

3. The apparatus of claim 2, wherein each pin of the plurality of test pins has a pin height of between about 30 micrometers to about 50 micrometers.

4. The apparatus of claim 3, wherein each ball of the plurality of balls has a ball height of between about 135 micrometers to about 155 micrometers.

5. The apparatus of claim 2, wherein the plurality of test pins is formed from a conductive paste.

6. The apparatus of claim 2, wherein the plurality of test pins are attached to a printed circuit board using a land grid array (LGA) and wherein the plurality of balls are attached to the printed circuit board using a ball grid array (BGA).

7. The apparatus of claim 2, wherein the individual test pins of the plurality of test pins are configured to be accessed to test one or more parameters of an application processor die.

8. The apparatus of claim 1, wherein a solder resist material covers individual test pads of the plurality of test pads.

9. The apparatus of claim 1, wherein each of the plurality of test pads has a generally circular, oval, square, or rectangular shape.

10. The apparatus of claim 1, wherein at least one test pad of the plurality of test pads is located between four adjacent balls of the plurality of balls.

11. The apparatus of claim 1, wherein individual test pads of the plurality of test pads are connected to one or more sense lines in the package.

12. The apparatus of claim 1, wherein individual test pads of the plurality of test pads are configured to be accessed to test one or more parameters of a Power Distribution Network (PDN).

13. The apparatus of claim 1, wherein individual test pads of the plurality of test pads are configured to be accessed to test one or more parameters of a power management integrated circuit (PMIC).

14. The apparatus of claim 1, wherein the package comprises a System-on-a-chip (SOC).

15. The apparatus of claim 1, wherein the apparatus is selected from the group consisting of: a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a base station, and a device in an automotive vehicle.

16. A method of fabricating a package, the method comprising:
attaching components to a top surface of a substrate;
forming a plurality of ball pads on a bottom surface of the substrate;
attaching a plurality of balls to a plurality of ball pads, wherein individual balls of the plurality of balls are attached to individual ball pads of the plurality of ball pads; and
forming a plurality of test pads on the bottom surface of the substrate.

17. The method of claim 16, further comprising:
attaching a plurality of test pins to the plurality of test pads, wherein individual test pins are attached to individual test pads of the plurality of test pads, and wherein the individual test pins are lower in height than the individual balls.

18. The method of claim 17, further comprising:
applying a solder resist to a pin-attach layer, wherein the plurality of ball pads and the plurality of test pads are not covered by the solder resist; and
substantially simultaneously extruding and curing the plurality of test pins to the pin-attach layer, wherein individual test pins are extruded and cured on top of individual test pads of the plurality of test pads.

19. The method of claim 18, wherein substantially simultaneously extruding and curing the plurality of test pins to the pin-attach layer comprises:
extruding a conductive paste using a nozzle of an inkjet printer to create the plurality of test pins; and
curing the plurality of test pins using a laser flash lamp as the plurality of test pins are being extruded.

20. The method of claim 17, wherein the package is mounted on to a printed circuit board (PCB) using a reflow process comprising:
attaching the plurality of test pins to the printed circuit board using a land grid array (LGA) attachment process; and
attaching the plurality of balls to the printed circuit board using a ball grid array (BGA) attachment process.

21. The method of claim 17, wherein the individual test pins of the plurality of test pins are connected to one or more sense lines located in the package.

22. The method of claim 21, further comprising:
mounting the package on a printed circuit board (PCB); and
accessing the one or more sense lines using one or more individual test pins.

23. The method of claim 22, further comprising:
testing, using the one or more sense lines, one or more parameters of at least one of a Power Distribution Network (PDN), a power management integrated circuit (PMIC), or an application processor die.

24. The method of claim 17, wherein each pin of the plurality of test pins has a height of between about 30 micrometers to about 50 micrometers.

25. The method of claim 17, wherein the plurality of test pins has a generally circular, oval, square, or rectangular shape.

26. The method of claim 17, wherein at least one test pin of the plurality of test pins is located between four adjacent balls of the plurality of balls.

27. The method of claim 16, further comprising:
performing an organic solderability preservatives (OSP) finish; or
performing an electrolytic Nickle-Gold (Ni—Au) finish in which a layer of Gold is plated over a base of electroplated nickel.

28. The method of claim 16, wherein each of the plurality of balls has a height of between about 135 micrometers to about 155 micrometers.

29. The method of claim 16, wherein the package comprises a System-on-a-chip (SOC).

30. The method of claim 16, wherein the package is incorporated into a device that is selected from the group consisting of: a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a base station, and an automotive-based device in an automotive vehicle.
